(19) United States
(12) Patent Application Publication
(10) Pub. No.: US 2026/0302539 A1
(43) Pub. Date: Oct. 1, 2026

(54) BUS BAR MODULE

(71) Applicants: Yazaki Corporation, Tokyo (JP); Toyota Jidosha Kabushiki Kaisha, Toyota-shi (JP)

(72) Inventors: Kaname Tsukamoto, Toyota-Shi (JP); Tomohiro Matsushima, Shizuoka (JP); Takuomi Wada, Shizuoka (JP); Kenta Tanaka, Shizuoka (JP)

(21) Appl. No.: 19/576,804

(22) Filed: Mar. 24, 2026

(30) Foreign Application Priority Data
Mar. 26, 2025 (JP) 2025-051286

(51) Int. Cl. H01M 50/503; H01M 50/519; H05K 1/02

(52) U.S. Cl. CPC H01M 50/503; H01M 50/519; H05K 1/0277; H05K 2201/10151; H05K 2201/10272

(57) ABSTRACT

A bus bar module includes a flexible printed circuit board including a trunk line portion and a branch portion branching from the trunk line portion, a thermistor mounted on the branch portion, a bus bar connected to the flexible printed circuit board, a case that includes a routing path supporting the trunk line portion and is capable of being assembled with a battery module, and an elastic member that presses, toward a battery cell of the battery module, a predetermined region of the branch portion where the thermistor is disposed, in which the case includes a first surface facing the battery module and a second surface on an opposite side of the first surface, and the routing path is disposed on the second surface.

### CROSS-REFERENCE TO RELATED APPLICATION(S)

The present application claims priority to and incorporates by reference the entire contents of Japanese Patent Application No. 2025-051286 filed in Japan on March 26, 2025.

### BACKGROUND OF THE INVENTION

### 1. Field of the Invention

The present invention relates to a bus bar module.

### 2. Description of the Related Art

Conventionally, there is a technique of disposing a temperature sensor in a battery cell. Japanese Patent Application Laid-open No. 2011-17638 discloses a temperature sensor including a sensor body having a temperature measuring surface in contact with a measured portion at a distal end, and a locking arm extending from the sensor body.

Japanese Patent Application Laid-open No. 2024-153317 discloses a temperature sensor assembly including a temperature sensor and a case attached to a temperature-measured portion while holding the temperature sensor. The temperature sensor of Japanese Patent Application Laid-open No. 2024-153317 includes a flexible printed circuit board, a chip thermistor surface-mounted on the flexible printed circuit board, a metal heat receiving component in contact with the temperature-measured portion, and an elastic member assembled with the heat receiving component.

In a bus bar module including a flexible printed circuit board and a thermistor connected to the flexible printed circuit board, desirably, the flexible printed circuit board can be routed while expansion of the flexible printed circuit board in a width direction is suppressed. For example, in a case in which it is desired to route the flexible printed circuit board so as not to overlap a safety valve of a battery cell, it is preferable that a width of a routing region can be narrowed.

### SUMMARY OF THE INVENTION

An object of the present invention is to provide a bus bar module capable of routing a flexible printed circuit board while suppressing expansion of the flexible printed circuit board in a width direction.

A bus bar module according to one aspect of the present invention includes a flexible printed circuit board including a trunk line portion and a branch portion branching from the trunk line portion; a thermistor mounted on the branch portion; a bus bar connected to the flexible printed circuit board; a case having a routing path supporting the trunk line portion, the case being capable of being assembled with a battery module; and an elastic member configured to press, toward a battery cell of the battery module, a predetermined region of the branch portion, the predetermined region having the thermistor disposed therein, wherein the case has a first surface facing the battery module and a second surface on an opposite side of the first surface, the routing path is disposed on the second surface, the elastic member is assembled with the case from a side of the first surface, and a position of the elastic member in a plan view of the case is a position overlapping the routing path.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a side view of a bus bar module and a battery module according to an embodiment;

FIG. 2 is an exploded perspective view of the bus bar module according to the embodiment;

FIG. 3 is a plan view of the bus bar module according to the embodiment;

FIG. 4 is a plan view of a flexible printed circuit board according to the embodiment;

FIG. 5 is a perspective view of the flexible printed circuit board according to the embodiment;

FIG. 6 is a perspective view of a case according to the embodiment;

FIG. 7 is a perspective view of a branch portion and a pressing structure according to the embodiment;

FIG. 8 is an exploded perspective view of the pressing structure according to the embodiment;

FIG. 9 is a cross-sectional view of the bus bar module and the battery module according to the embodiment; and

FIG. 10 is a perspective view of the bus bar module according to the embodiment.

### DETAILED DESCRIPTION OF THE PREFERRED EMBODIMENTS

Hereinafter, a bus bar module according to an embodiment of the present invention will be described in detail with reference to the drawings. It is noted that the present invention is not limited by the embodiment. In addition, configuration elements in the following embodiment include those that can be easily assumed by those skilled in the art or those that are substantially the same.

### Embodiment

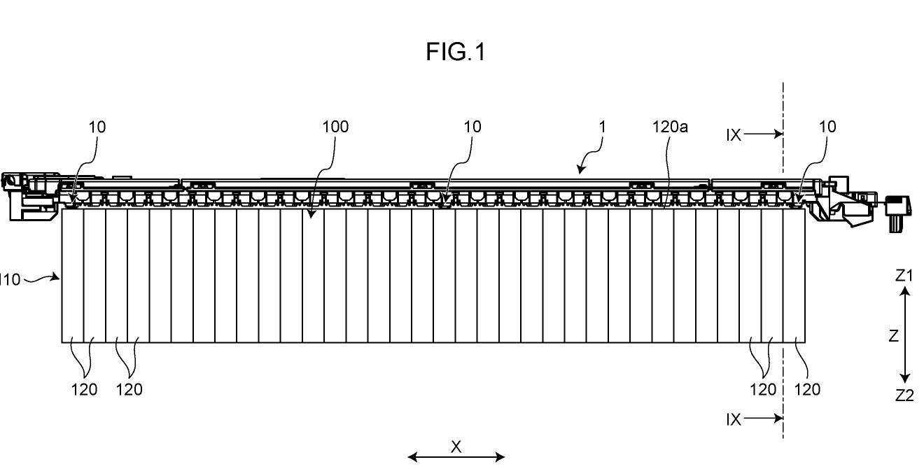

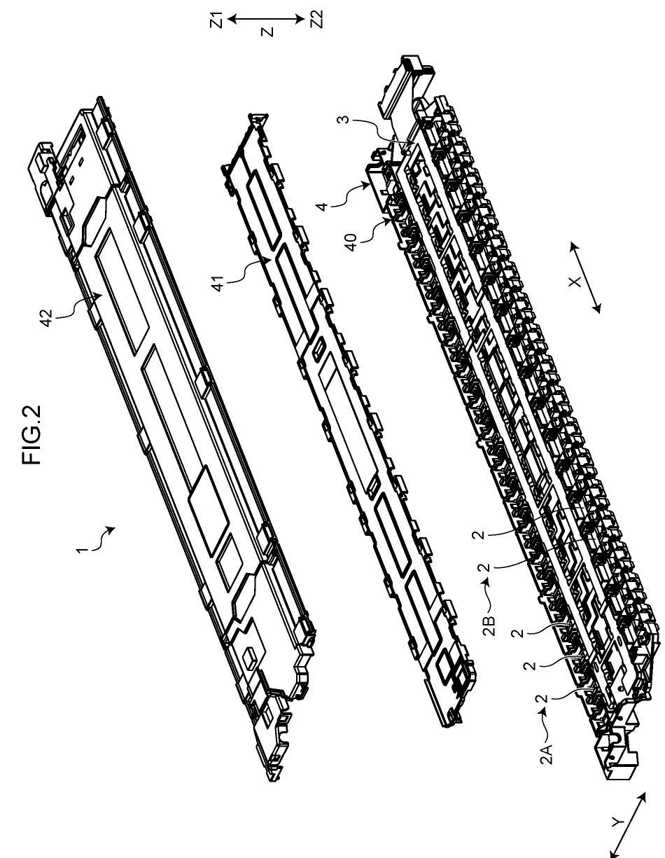

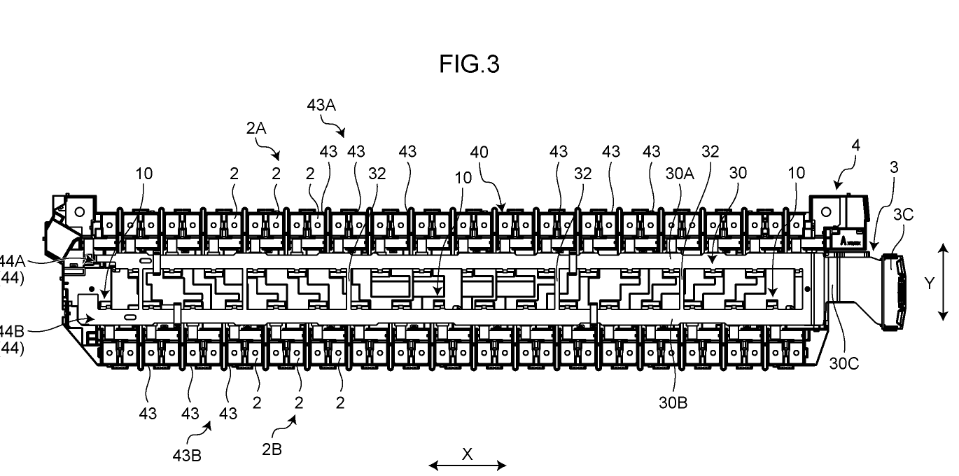

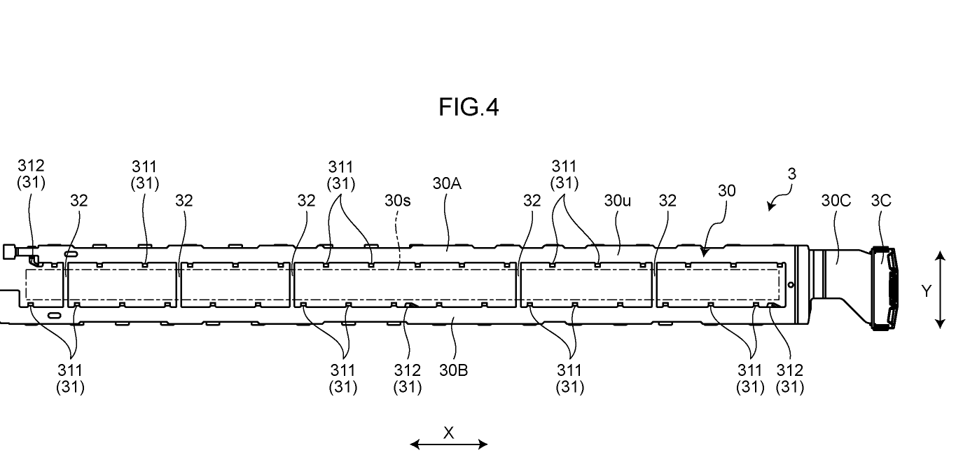

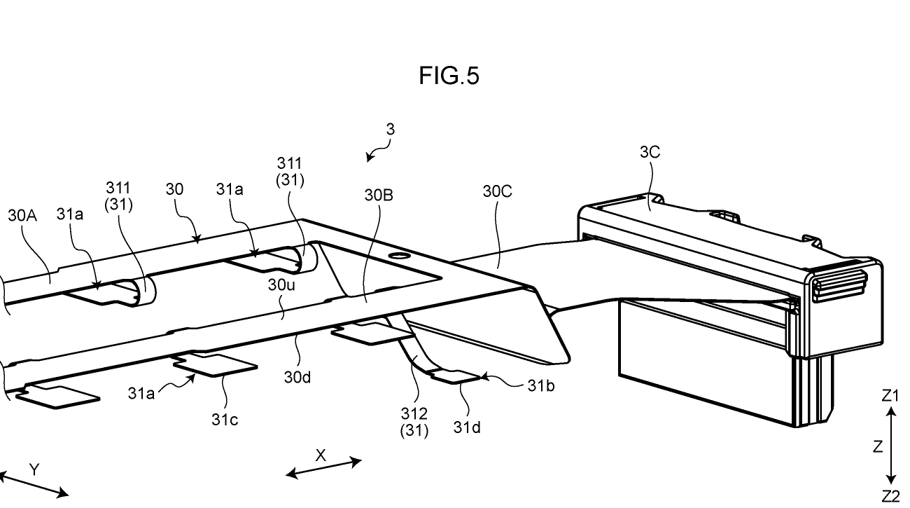

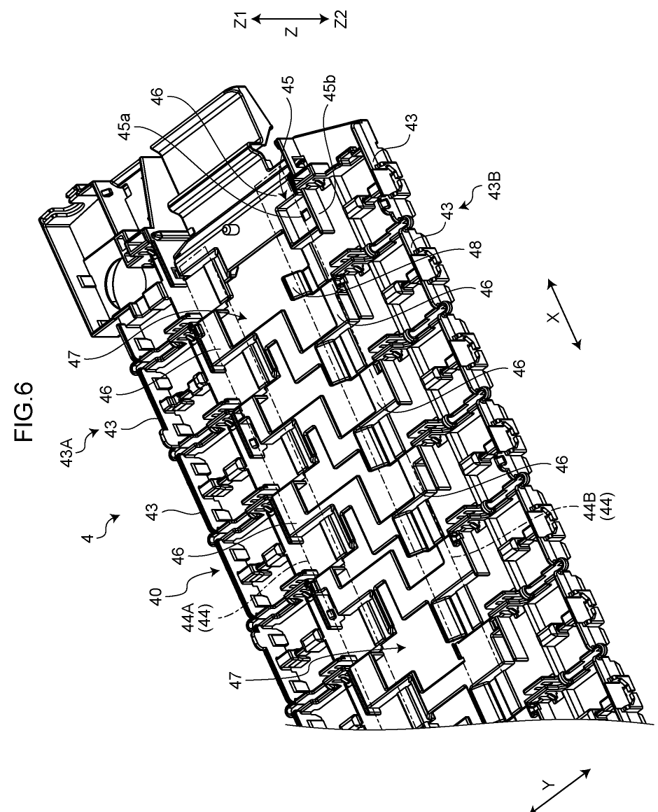

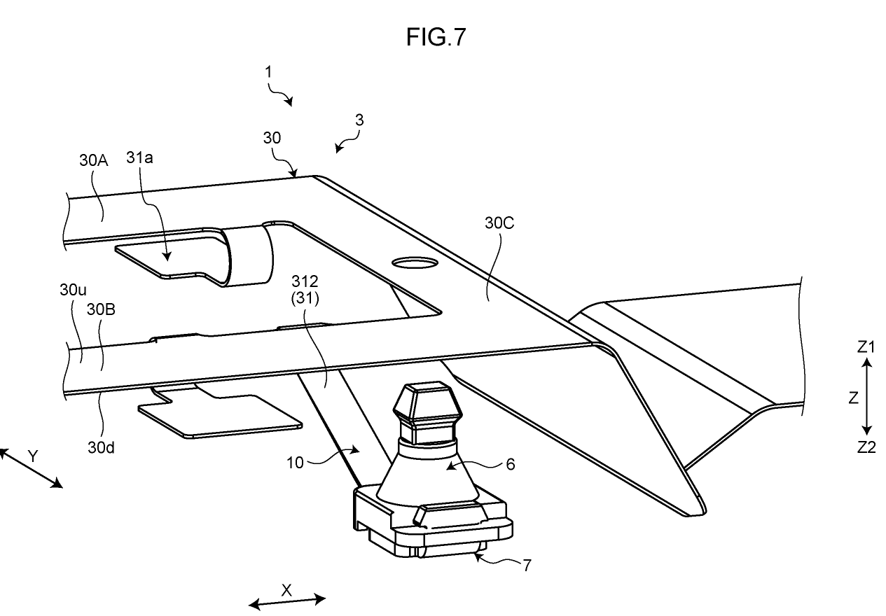

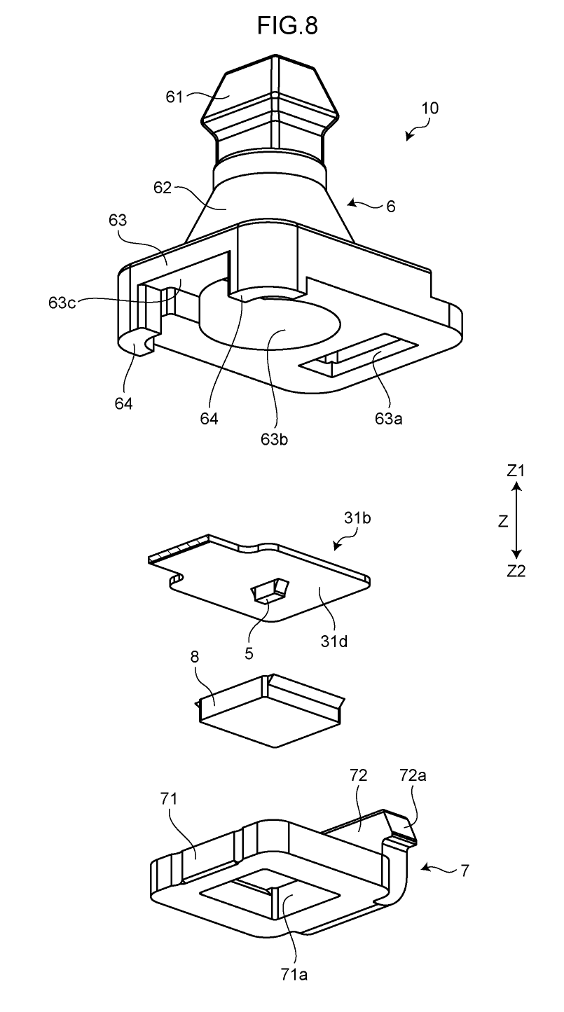

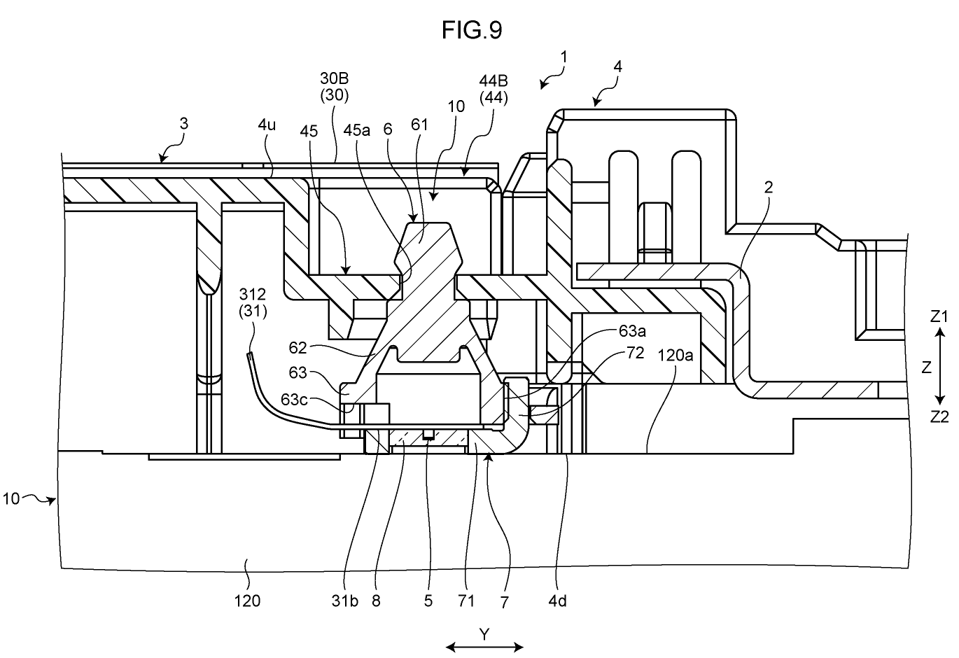

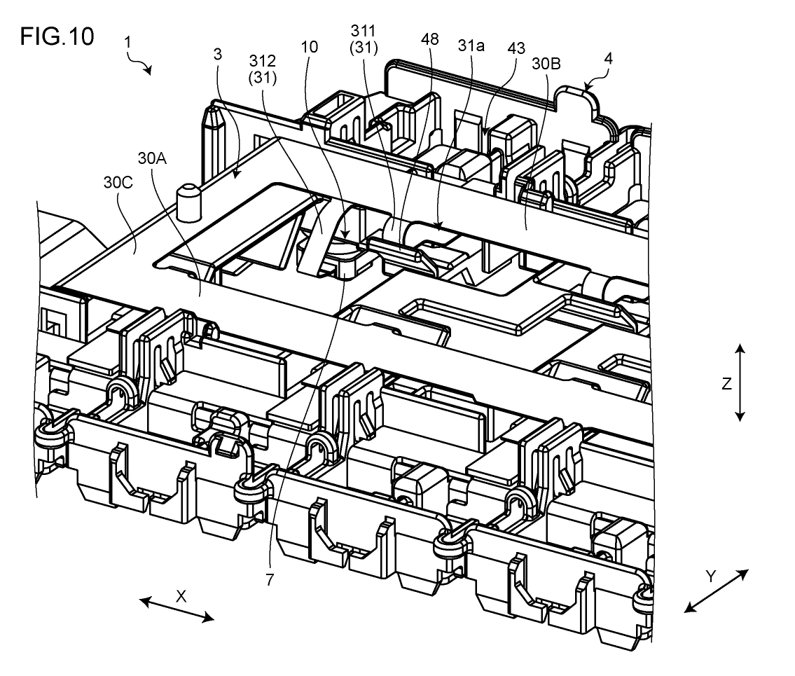

An embodiment will be described with reference to FIGS. 1 to 10. The present embodiment relates to a bus bar module. FIG. 1 is a side view of a bus bar module and a battery module according to an embodiment, FIG. 2 is an exploded perspective view of the bus bar module according to the embodiment, FIG. 3 is a plan view of the bus bar module according to the embodiment, FIG. 4 is a plan view of a flexible printed circuit board according to the embodiment, FIG. 5 is a perspective view of the flexible printed circuit board according to the embodiment, FIG. 6 is a perspective view of a case according to the embodiment, FIG. 7 is a perspective view of a branch portion and a pressing structure according to the embodiment, FIG. 8 is an exploded perspective view of the pressing structure according to the embodiment, FIG. 9 is a cross-sectional view of the bus bar module and the battery module according to the embodiment, and FIG. 10 is a perspective view of the bus bar module according to the embodiment. FIG. 9 illustrates a cross section taken along line IX-IX in FIG. 1.

As illustrated in FIGS. 1, 2, 9, and the like, a bus bar module 1 includes a plurality of bus bars 2, a flexible printed circuit board 3, a case 4, a thermistor 5, and a pressing structure 10. The bus bar module 1 is applied to, for example, a battery pack 100. The battery pack 100 is mounted as a power source on a vehicle such as an automobile. The battery pack 100 illustrated in FIG. 1 has a battery module 110. The battery module 110 includes a plurality of battery cells 120 arranged in a first direction X. The bus bar module 1 of the present embodiment can be assembled with the battery module 110. For example, the battery pack 100 is mounted on the vehicle in such a way that the plurality of battery cells 120 are arranged in a vehicle front-and-rear direction or a vehicle width direction.

The bus bar 2 is formed of a conductive metal plate. The bus bar 2 electrically connects two adjacent battery cells 120. More specifically, the bus bar 2 is fixed to an electrode of one battery cell 120 and an electrode of the other battery cell 120, and electrically connects the two electrodes to each other.

The battery cell 120 in FIG. 1 has an electrode disposed on a top surface 120a facing a first side Z1 in a third direction Z. The third direction Z is a direction orthogonal to the first direction X, and is, for example, a vehicle vertical direction. The first side Z1 is, for example, a vehicle upper side. In the present specification, a direction orthogonal to both the first direction X and the third direction Z is referred to as a second direction Y. The second direction Y is a width direction of the battery cell 120. The battery cell 120 has a pair of electrodes arranged in the second direction Y. One of the pair of electrodes is a positive electrode, and the other is a negative electrode.

As illustrated in FIGS. 2 and 3, the plurality of bus bars 2 include a first bus bar group 2A and a second bus bar group 2B. Each of the first bus bar group 2A and the second bus bar group 2B includes a plurality of bus bars 2 arranged in the first direction X. The first bus bar group 2A is disposed at one end portion of the bus bar module 1 in the second direction Y. The second bus bar group 2B is disposed at the other end portion of the bus bar module 1 in the second direction Y. The bus bar 2 of the first bus bar group 2A is connected to one of the pair of electrodes included in the battery cell 120, and the bus bar 2 of the second bus bar group 2B is connected to the other one of the pair of electrodes. The bus bar 2 may connect two adjacent battery cells 120 in series.

The case 4 is a member that holds the bus bar 2, the flexible printed circuit board 3, and the pressing structure 10, and can be assembled with the battery module 110. The case 4 is molded using, for example, an insulating synthetic resin.

As illustrated in FIG. 2, the case 4 of the present embodiment includes a case main body 40, a first cover 41, and a second cover 42. The case main body 40 is formed to be able to hold the plurality of bus bars 2, the flexible printed circuit board 3, and the pressing structure 10 and to be assembled with the battery module 110. The illustrated case main body 40 has a substantially rectangular shape in plan view.

The first cover 41 is assembled with the case main body 40 to cover the flexible printed circuit board 3. That is, the flexible printed circuit board 3 is accommodated between the case main body 40 and the first cover 41. The second cover 42 is configured to be assembled with the case main body 40 to cover the entirety of the case main body 40. The second cover 42 covers the bus bar 2, the first cover 41, and the flexible printed circuit board 3. In a state in which the bus bar module 1 is assembled with the battery module 110, the first cover 41 is positioned on the first side Z1 with respect to the case main body 40, and the second cover 42 is positioned on the first side Z1 with respect to the case main body 40 and the first cover 41.

As illustrated in FIGS. 3 and 6, the case main body 40 includes a plurality of holding portions 43 that hold the bus bars 2. More specifically, the case main body 40 includes a plurality of holding portions 43A corresponding to the first bus bar group 2A and a plurality of holding portions 43B corresponding to the second bus bar group 2B. The plurality of holding portions 43A and 43B corresponding to the bus bar groups 2A and 2B are arranged in the first direction X.

As illustrated in FIGS. 3 and 4, the flexible printed circuit board 3 of the present embodiment includes a trunk line portion 30 having a substantially U shape, a plurality of branch portions 31, and a connecting portion 32. The flexible printed circuit board 3 includes a base film, a coverlay, and a conductive layer. The base film and the coverlay are flexible insulating resin layers. The conductive layer is sandwiched between and protected by the base film and the coverlay. The conductive layer is, for example, a conductive metal foil, and has a plurality of circuit patterns.

A plurality of circuit patterns are arranged in the trunk line portion 30. The plurality of circuit patterns include a voltage detection line connected to the bus bar 2 and a temperature detection line connected to the thermistor 5. These detection lines are connected to a circuit of a monitoring device via a connector 3C. The connector 3C is connected to an end portion of the flexible printed circuit board 3. The monitoring device monitors the battery pack 100 based on information acquired through the detection line.

As illustrated in FIG. 4, the trunk line portion 30 includes a first trunk line 30A, a second trunk line 30B, and a merging portion 30C. The first trunk line 30A corresponds to the first bus bar group 2A, and the second trunk line 30B corresponds to the second bus bar group 2B. The two trunk lines 30A and 30B extend in parallel in the first direction X. An opening region 30s is provided between the first trunk line 30A and the second trunk line 30B. The opening region 30s is provided, for example, according to a position of a safety valve of the battery cell 120.

When the safety valve is disposed at a central portion of the battery cell 120 in the second direction Y, the opening region 30s is set so as to open a space above the safety valve. The opening region 30s is a region that allows a space portion below the trunk line portion 30 to communicate with a space portion above the trunk line portion 30. The opening region 30s has a plurality of openings partitioned by the connecting portion 32. The first trunk line 30A and the second trunk line 30B are arranged on both sides in the second direction Y with the opening region 30s interposed therebetween.

The merging portion 30C is connected to end portions of the first trunk line 30A and the second trunk line 30B in the first direction X. The connector 3C is connected to an end portion of the merging portion 30C. A circuit pattern of the first trunk line 30A and a circuit pattern of the second trunk line 30B are connected to the connector 3C with the merging portion 30C interposed therebetween.

The connecting portion 32 connects the first trunk line 30A to the second trunk line 30B, and extends in the second direction Y. The illustrated flexible printed circuit board 3 has a plurality of connecting portions 32. The plurality of connecting portions 32 are disposed with intervals therebetween in the first direction X. Since the first trunk line 30A and the second trunk line 30B are connected to each other by the connecting portion 32, the flexible printed circuit board 3 can be easily handled.

The branch portion 31 branches from the trunk lines 30A and 30B in the second direction Y. The plurality of branch portions 31 include a first branch portion 311 and a second branch portion 312. The branch portions 31 are connected to the end portions of the trunk lines 30A and 30B on the opening region 30s side. That is, the branch portion 31 corresponding to the first trunk line 30A is connected to an edge of the first trunk line 30A on the side of the second trunk line 30B. The branch portion 31 corresponding to the first trunk line 30A is orthogonal to the first trunk line 30A. The branch portion 31 corresponding to the second trunk line 30B is connected to an edge of the second trunk line 30B on the side of the first trunk line 30A. The branch portion 31 corresponding to the second trunk line 30B is orthogonal to the second trunk line 30B. With such a configuration, all the branch portions 31 can be efficiently formed within a range of the opening region 30s. Therefore, a sheet area required for forming the flexible printed circuit board 3 can be reduced.

The first branch portion 311 is the branch portion 31 connected to the bus bar 2. The second branch portion 312 is the branch portion 31 connected to the thermistor 5. The first trunk line 30A and the second trunk line 30B are respectively connected to a plurality of first branch portions 311. The plurality of first branch portions 311 are arranged with intervals therebetween in the first direction X.

The trunk line portion 30 of the present embodiment is connected to a plurality of second branch portions 312. The number of second branch portions 312 corresponds to the number of thermistors 5 disposed in the battery module 110. The illustrated flexible printed circuit board 3 has three second branch portions 312. The second branch portions 312 are arranged one by one at both end portions of the trunk line portion 30 in the first direction X and at a central portion thereof in the first direction X. The branch portion 31 corresponding to the first trunk line 30A and the branch portion 31 corresponding to the second trunk line 30B are arranged with positions in the first direction X shifted from each other. That is, in a sheet when the flexible printed circuit board 3 is formed, the branch portion 31 connected to the first trunk line 30A and the branch portion 31 connected to the second trunk line 30B are alternately arranged in the opening region 30s.

As illustrated in FIGS. 3 and 6, the case main body 40 has a routing path 44. The routing path 44 includes a first routing path 44A and a second routing path 44B. The first routing path 44A is a routing path corresponding to the first trunk line 30A of the flexible printed circuit board 3. The second routing path 44B is a routing path facing the second trunk line 30B. The first routing path 44A and the second routing path 44B extend in the first direction X and are parallel to each other.

The first routing path 44A and the second routing path 44B are arranged on the center side in the second direction Y with respect to the holding portion 43. The first routing path 44A is adjacent to the holding portion 43A for the first bus bar group 2A, and the second routing path 44B is adjacent to the holding portion 43B for the second bus bar group 2B. An opening portion 47 is provided between the first routing path 44A and the second routing path 44B.

The routing path 44 has a plurality of support surfaces 46 arranged in the first direction X. The plurality of support surfaces 46 are planes facing the first side Z1 in the third direction Z, and are arranged corresponding to the respective holding portions 43. The support surface 46 supports the flexible printed circuit board 3 from the second side Z2 in the third direction Z.

As illustrated in FIG. 6, the case main body 40 includes a holding portion 45. The holding portion 45 is disposed corresponding to the second branch portion 312. As will be described later, the holding portion 45 is configured to be able to hold an elastic member 6 of the pressing structure 10. The holding portion 45 includes a through hole 45a and a frame 45b surrounding the through hole 45a. The through hole 45a penetrates the case main body 40 in the third direction Z. The holding portion 45 is disposed between two adjacent support surfaces 46. That is, the holding portion 45 is disposed so as to overlap the routing path 44 in plan view. The case 4 of the present embodiment has three holding portions 45 corresponding to three thermistors 5.

As illustrated in FIG. 5, the trunk line portion 30 has a first surface 30d and a second surface 30u. The first surface 30d is one of two main surfaces of the trunk line portion 30 and faces the battery module 110. In other words, the flexible printed circuit board 3 is routed with the first surface 30d oriented toward the second side Z2. The first surface 30d is supported by the support surface 46 of the case 4. The second surface 30u is the other one of the two main surfaces of the trunk line portion 30 and faces the side opposite to the battery module 110 side. The second surface 30u faces the first cover 41 of the case 4.

A connecting portion 31a connected to the bus bar 2 is provided at a distal end of the first branch portion 311. The connecting portion 31a has a mounting surface 31c. The mounting surface 31c of the first branch portion 311 is continuous with the second surface 30u of the trunk line portion 30.

A pad that can be bonded to the bus bar 2 and a chip fuse are disposed on the mounting surface 31c. The bus bar 2 is connected to a circuit pattern via the pad and the chip fuse. The first branch portion 311 is folded back in a U shape between the trunk line portion 30 and the connecting portion 31a. In other words, the first branch portion 311 is connected to the bus bar 2 with the mounting surface 31c facing the side opposite to the trunk line portion 30 side. In the bus bar module 1 of the present embodiment, the first branch portion 311 is folded back such that the first surface 30d of the trunk line portion 30 and the connecting portion 31a face each other in the third direction Z.

A connecting portion 31b connected to the thermistor 5 is provided at the distal end of the second branch portion 312. The connecting portion 31b has a mounting surface 31d. The mounting surface 31d of the second branch portion 312 is continuous with the second surface 30u of the trunk line portion 30.

The thermistor 5 is mounted on the mounting surface 31d. The second branch portion 312 is folded back in a U shape between the trunk line portion 30 and the connecting portion 31b. In other words, the second branch portion 312 is held in a state in which the mounting surface 31d faces the side opposite to the trunk line portion 30 side. In the bus bar module 1 of the present embodiment, the second branch portion 312 is folded back such that the first surface 30d of the trunk line portion 30 and the connecting portion 31b face each other in the third direction Z.

FIGS. 7 and 8 illustrate the pressing structure 10 of the present embodiment. In FIG. 7, the bus bar 2 and the case 4 are omitted for easy understanding of the structure and arrangement of the pressing structure 10. The pressing structure 10 includes the elastic member 6 and a support member 7. The elastic member 6 is an elastically deformable member and is formed of, for example, synthetic rubber such as EPDM. The elastic member 6 is stretchable in the third direction Z and can press the connecting portion 31b and the thermistor 5 toward the battery cell 120.

As illustrated in FIG. 8, the elastic member 6 includes a fitting portion 61, a cylindrical portion 62, and a pressing portion 63. The fitting portion 61, the cylindrical portion 62, and the pressing portion 63 are integrally molded. The fitting portion 61 is inserted into the through hole 45a in the case 4 and is held by the holding portion 45. The fitting portion 61 has a substantially spindle shape. That is, the shape of the fitting portion 61 is a shape in which a cross-sectional area of a central portion is large and the cross-sectional area decreases toward both ends of the fitting portion 61.

The pressing portion 63 is a portion that presses the connecting portion 31b of the flexible printed circuit board 3. The pressing portion 63 has a substantially rectangular plate shape. A through hole 63a, an opening portion 63b, and a notch 63c are formed in the pressing portion 63.

The through hole 63a has a shape into which a fitting portion 72 of the support member 7 can be inserted. The through hole 63a is formed in the vicinity of one side of the pressing portion 63 and passes through the pressing portion 63. The illustrated shape of the through hole 63a is rectangular. However, the shape of the through hole 63a is not limited to a rectangle. The shape of the through hole 63a may be any shape as long as the fitting portion 72 of the support member 7 can be inserted into the through hole 63a and the fitting portion 72 can be locked therein. The shape of the through hole 63a may be a polygon different from a rectangle, a circle, or the like. The cylindrical portion 62 is a cylindrical portion disposed between the fitting portion 61 and the pressing portion 63. The cylindrical portion 62 of the present embodiment has a hollow truncated cone shape. The cylindrical portion 62 has a tapered shape that becomes thinner toward the fitting portion 61. The opening portion 63b in the pressing portion 63 communicates with an internal space of the cylindrical portion 62.

The elastic member 6 has two protruding portions 64 protruding from the pressing portion 63. The two protruding portions 64 are disposed at two adjacent corner portions of the pressing portion 63 and hold the support member 7. The protruding portion 64 protrudes toward the side opposite to the cylindrical portion 62 side.

The notch 63c is provided between the two protruding portions 64. The notch 63c is formed for the second branch portion 312 of the flexible printed circuit board 3 to pass therethrough. The notch 63c forms a gap between the support member 7 and a pressing surface of the pressing portion 63 so that the pressing portion 63 is hardly rotated or deformed by reaction force of the second branch portion 312.

The support member 7 is a member that is fixed to the connecting portion 31b of the flexible printed circuit board 3 and supports the connecting portion 31b and the thermistor 5. The support member 7 has a function as a heat collector or a heat transfer body that collects heat of the battery cell 120 to the thermistor 5. The support member 7 is made of metal such as, for example, aluminum.

The support member 7 includes a rectangular frame portion 71 and the fitting portion 72. The frame portion 71 is provided with a through hole 71a corresponding to the thermistor 5. The frame portion 71 is fixed to the mounting surface 31d of the connecting portion 31b so as to surround the thermistor 5. A fixing means of the frame portion 71 with respect to the mounting surface 31d is, for example, solder.

The fitting portion 72 is inserted into the through hole 63a in the elastic member 6. The support member 7 is bent at a substantially right angle so that the fitting portion 72 is erected with respect to the frame portion 71. The shape of the fitting portion 72 is substantially rectangular. The fitting portion 72 has a protrusion 72a locked by the pressing portion 63 of the elastic member 6. The protrusion 72a protrudes toward both sides in the width direction. The through hole 71a in the frame portion 71 is filled with a potting agent 8 so as to seal the thermistor 5. The potting agent 8 protects the thermistor 5 against moisture and the like.

FIG. 9 illustrates a cross section of the bus bar module 1 assembled with the battery module 110. The case 4 is fixed to the battery module 110. The case 4 has a first surface 4d and a second surface 4u. The first surface 4d and the second surface 4u face opposite sides to each other. The routing path 44 is disposed on the second surface 4u. The case 4 is assembled with the battery module 110 with the first surface 4d facing the second side Z2 in the third direction Z. That is, the first surface 4d faces the top surface 120a of the battery module 110. The second surface 4u faces the first side Z1 in the third direction Z and supports the trunk line portion 30.

The pressing structure 10 is held by the holding portion 45 of the case 4 while holding the connecting portion 31b of the flexible printed circuit board 3. More specifically, the fitting portion 61 of the elastic member 6 is inserted into the through hole 45a from the second side Z2 and is held by the holding portion 45. In other words, the elastic member 6 is assembled with the case 4 from the first surface 4d side. The cylindrical portion 62 and the pressing portion 63 protrude from the holding portion 45 toward the second side Z2 in the third direction Z.

The fitting portion 72 of the support member 7 is inserted into the through hole 63a in the pressing portion 63 and is held by the pressing portion 63. The support member 7 sandwiches the connecting portion 31b between the frame portion 71 and the pressing portion 63, and holds the connecting portion 31b.

For example, the support member 7 is assembled with the elastic member 6 previously attached to the case 4. In this case, first, the single elastic member 6 is fixed to the holding portion 45 of the case 4. Thereafter, the support member 7 fixed to the connecting portion 31b is assembled with the elastic member 6. When the support member 7 is assembled with the elastic member 6, the second branch portion 312 is folded back in a U shape. A timing at which the elastic member 6 and the support member 7 are assembled with each other is not limited to the above timing. The elastic member 6 may be fixed to the case 4 after being assembled with the support member 7.

When the case 4 is assembled with the battery module 110, the holding portion 45 presses the elastic member 6 toward the battery cell 120. That is, the holding portion 45 presses the cylindrical portion 62 of the elastic member 6 toward the second side Z2 in the third direction Z. The elastic member 6 presses the support member 7 and the thermistor 5 toward the top surface 120a of the battery cell 120. More specifically, the elastic member 6 presses the connecting portion 31b of the flexible printed circuit board 3 and the frame portion 71 of the support member 7 against the top surface 120a of the battery cell 120. At this time, the elastic member 6 presses the frame portion 71 while being elastically deformed, and can bring the frame portion 71 into surface contact with the top surface 120a.

In the pressing structure 10 of the present embodiment, the thermistor 5 can be appropriately pressed toward the battery cell 120 by the elastic member 6. Further, by using the elastic member 6 that can expand and contract in the third direction Z, the pressing structure 10 can be downsized. As a comparative example, a structure in which the thermistor 5 is pressed by a locking arm that is flexurally deformed will be examined. The elastic member 6 of the present embodiment can be downsized at least in the third direction Z with respect to the locking arm of the comparative example. Therefore, the bus bar module 1 of the present embodiment can be reduced in height.

In the bus bar module 1 of the present embodiment, as illustrated in FIG. 9, the elastic member 6 overlaps the routing path 44 in the third direction Z. In other words, in a plan view of the bus bar module 1, the elastic member 6 overlaps the trunk line portion 30 of the flexible printed circuit board 3. Accordingly, the bus bar module 1 can be downsized in the second direction Y. More specifically, the thermistor 5 and the pressing structure 10 are accommodated in a region between the trunk line portion 30 and the battery cell 120, so that expansion of the bus bar module 1 in the second direction Y is suppressed. In other words, it is possible to reduce the width in the second direction Y when the bus bar module 1 is projected onto a plane orthogonal to the third direction Z.

As illustrated in FIG. 10, the second branch portion 312 is folded back in a U shape so as to position the pressing structure 10 below the trunk line portion 30. The first branch portion 311 is folded back in a U shape to pass through a low side of the trunk line portion 30, and is connected to the bus bar 2 of the holding portion 43. The case 4 has a support wall 48 that supports the first branch portion 311. The support wall 48 is inclined so as to allow the first branch portion 311 to enter the lower side of the trunk line portion 30. The support wall 48 supports a curved portion of the first branch portion 311 so as to maintain the shape of the first branch portion 311 in the U shape.

Since each of the branch portions 311 and 312 is folded back in the U shape, an open space having a sufficient width is formed between two trunk lines 30A and 30B. That is, in a case in which a safety valve is disposed between two electrodes in the battery cell 120, the branch portions 311 and 312 are routed while avoiding a space above the safety valve. As a result, the flexible printed circuit board 3 can be routed so as not to overlap the safety valve of the battery cell 120.

As described above, the bus bar module 1 of the present embodiment includes the flexible printed circuit board 3, the thermistor 5, the bus bar 2, the case 4, and the elastic member 6. The flexible printed circuit board 3 includes the trunk line portion 30 and the branch portion 31 branching from the trunk line portion 30. The thermistor 5 is mounted on the branch portion 31. The bus bar 2 is connected to the flexible printed circuit board 3. The case 4 has the routing path 44 that supports the trunk line portion 30, and can be assembled with the battery module 110. The elastic member 6 presses the connecting portion 31b of the branch portion 31 where the thermistor 5 is disposed toward the battery cell 120 of the battery module 110. The connecting portion 31b is an example of a predetermined region where the thermistor 5 is disposed.

The case 4 has the first surface 4d facing the battery module 110 and the second surface 4u which is a surface on the opposite side of the first surface 4d. The routing path 44 is disposed on the second surface 4u. The elastic member 6 is assembled with the case 4 from the first surface 4d side. The position of the elastic member 6 in plan view of the case 4 is a position overlapping the routing path 44. According to the bus bar module 1 of the present embodiment, the flexible printed circuit board 3 can be routed while expansion of the flexible printed circuit board 3 in the width direction is suppressed.

The branch portion 31 of the present embodiment is folded back so as to position the elastic member 6 between the trunk line portion 30 and the battery cell 120. The expansion of the branch portion 31 in the width direction is suppressed by routing of such a folded shape.

The pressing structure 10 may not include the support member 7. In this case, the connecting portion 31b may be fixed to the elastic member 6. The attachment structure of the elastic member 6 to the case 4 is not limited to a structure in which the fitting portion 61 is inserted into the through hole 45a. For example, the elastic member 6 may be press-fitted into the case 4, or may be held by the case 4 in another structure.

The contents disclosed in the above embodiments can be appropriately combined with each other and executed.

In a bus bar module according to the present embodiment, a position of an elastic member in a plan view of a case is a position overlapping a routing path. According to the bus bar module of the present embodiment, there is an effect that a flexible printed circuit board can be routed while expansion of the flexible printed circuit board in a width direction is suppressed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A bus bar module comprising:
a flexible printed circuit board including a trunk line portion and a branch portion branching from the trunk line portion;
a thermistor mounted on the branch portion;
a bus bar connected to the flexible printed circuit board;
a case having a routing path supporting the trunk line portion, the case being capable of being assembled with a battery module; and
an elastic member configured to press, toward a battery cell of the battery module, a predetermined region of the branch portion, the predetermined region having the thermistor disposed therein, wherein
the case has a first surface facing the battery module and a second surface on an opposite side of the first surface,
the routing path is disposed on the second surface,
the elastic member is assembled with the case from a side of the first surface, and
a position of the elastic member in a plan view of the case is a position overlapping the routing path.

2. The bus bar module according to claim 1, wherein
the branch portion is folded back so as to position the elastic member between the trunk line portion and the battery cell.
